(19) United States
(12) Patent Application Publication
(10) Pub. No.: US 2013/0202794 A1
(43) Pub. Date: Aug. 8, 2013

(54) METAL FILM DEPOSITION

(71) Applicants: Christian Dussarrat, Tokyo (JP); Vincent M. Omarjee, Grenoble (FR)

(72) Inventors: Christian Dussarrat, Tokyo (JP); Vincent M. Omarjee, Grenoble (FR)

(73) Assignee: American Air Liquide, Inc., Fremont, CA (US)

(21) Appl. No.: 13/811,472

(22) PCT Filed: May 27, 2011
(86) PCT No.: PCT/US11/38320

§ 371 Date: Apr. 8, 2013

Related U.S. Application Data
(60) Provisional application No. 61/469,522, filed on Mar. 30, 2011.
(60) Provisional application No. 61/366,810, filed on Jul. 22, 2010.

(51) Int. Cl. C23C 16/455

(52) U.S. Cl. CPC C23C 16/45527
USPC 427/252

(57) ABSTRACT

Disclosed are modified Atomic Layer Deposition processes used to deposit metal films on a substrate.

### CROSS-REFERENCE TO RELATED APPLICATIONS

This application claims the benefit of U.S. Provisional Application No. 61/366,810, filed Jul. 22, 2010 and 61/469,522 filed Mar. 30, 2011, the entire contents of which are incorporated herein by reference.

### BACKGROUND

Atomic Layer Deposition (ALD) is a process used to deposit very thin films on a substrate. Typical film thicknesses may vary from several angstroms to several hundreds of microns, depending on the specific deposition process.

In the standard ALD process, the vapor phase of a precursor is introduced into the reactor, where it is contacted with a suitable substrate. Excess precursor may then be removed from the reactor by purging with an inert gas and/or evacuating the reactor. A reactant (e.g., O₃ or NH₃) is introduced into the reactor, where it reacts with the absorbed precursor in a self-limiting manner. Any excess reactant is removed from the reactor by purging with an inert gas and/or evacuating the reactor. If the desired film is a metal film, this two-step process may provide the desired film thickness or may be repeated until a film having the necessary thickness has been obtained.

Alternatively, if the desired film is a bimetal film, the two-step process above may be followed by introduction of the vapor of a second metal-containing precursor into the reactor. The second metal-containing precursor will be selected based on the nature of the bimetal film being deposited. After introduction into the reactor, the second metal-containing precursor is contacted with the substrate. Any excess second metal-containing precursor is removed from the reactor by purging and/or evacuating the reactor. Once again, a reactant may be introduced into the reactor to react with the second metal-containing precursor. Excess reactant is removed from the reactor by purging and/or evacuating the reactor. If a desired film thickness has been achieved, the process may be terminated. However, if a thicker film is desired, the entire four-step process may be repeated. By alternating the provision of the metal-containing precursor, second metal-containing precursor, and reactant, a film of desired composition and thickness can be deposited.

Unfortunately, to date, the standard ALD process has not been able to successfully deposit all of the films of interest in the manufacture of semiconductor, photovoltaic, LCD-TFT, or flat panel type devices.

O'Meara et al. (ElectroChemical Society 210^{th} Meeting, abstract 1064) presented a molecular layer deposition process to improve SiN deposition. Dichlorosilane (DCS) was used. In the standard CVD process, SiN deposition using DCS+NH₃ does not occur at temperature below 600° C. Using an alternative method derived from Atomic Layer Deposition (ALD), O'Meara et al. demonstrated the feasibility of growing thin SiN layers using DCS and ammonia at ˜500° C. In this alternative method, DCS is introduced alone at a high flow rate and relatively high pressure (˜6 Torr/800 Pa), then the system is purged before introducing NH₃ alone (again ˜6 Torr/800 Pa). Long introduction times were used to allow saturation of the surface. A linear increase of film thickness with number of cycles was demonstrated. However, the time required per cycle is in the order or 24 minutes which, from a manufacturing point of view, is not cost competitive. Higher temperatures were tested, but resulted in decomposition of DCS and non-uniform film growth.

Nakajima and al. (Applied Physics Letters 79 (2001) 665) described a method that is similar in concept. Nakajima et al. alternate a pulse of SiCl₄ at 375° C. and 200 Torr (26,664 Pa) then purge the chamber before introducing NH₃ but with a substrate temperature ˜550° C. and a pressure of 500 Torr (66,661 Pa). One complete cycle took approximately 10 minutes. This process leads to the formation of an insulating silicon nitride layer and requires the use of a co-reactant.

US Pat App 2006/286810 to Delabie et al. disclose an ALD cycle comprising a pulse of HfCl₂ at 300° C., increasing the temperature to 420° C. for 2 minutes, and then cooling the temperature for 4 minutes in Table 2. The resulting film is HfO₂, even without the direct introduction of a H₂O reactant (para 0123). The oxygen-source is assumed to be moisture coming from the residuals present in the transport module (para 0122). However, the resulting film has high Cl-content (para 0123).

A need remains for ALD processes that deposit metal films of interest in the manufacture of semiconductor, photovoltaic, LCD-TFT, or flat panel type devices.

### SUMMARY

Disclosed are methods for depositing a metal film onto one or more substrates. The disclosed methods include setting a temperature in a reactor containing at least one substrate, introducing a pulse of a metal-containing precursor into the reactor, saturating a surface of the at least one substrate with at least part of the metal-containing precursor, and removing a portion of the at least part of the metal-containing precursor to form a metal layer exclusively by increasing the temperature of the reactor to a temperature that is higher than a decomposition temperature of the metal-containing precursor. The concentration of the metal in the resulting metal layer ranges from approximately 70 atomic % to approximately 100 atomic %, preferably approximately 90 atomic % to approximately 100 atomic %.

Alternatively, the disclosed methods include introducing a pulse of a metal-containing precursor into a reactor having at least one substrate disposed therein, the reactor being at a temperature that is lower than a decomposition temperature of the metal-containing precursor, saturating a surface of the at least one substrate with at least part of the metal-containing precursor, and forming a metal layer on the at least one substrate exclusively by increasing the temperature of the reactor to a temperature that is higher than the decomposition temperature of the metal-containing precursor.

In another alternative, the disclosed methods consist essentially of setting a temperature in a reactor containing at least one substrate, introducing a pulse of a metal-containing precursor into the reactor, saturating a surface of the at least one substrate with at least part of the metal-containing precursor, removing a portion of the at least part of the metal-containing precursor to form a metal layer by increasing the temperature of the reactor to a temperature that is higher than a decomposition temperature of the metal-containing precursor during the purge cycle, and repeating these steps until a metal film having the desired thickness is obtained.

In another alternative, the disclosed methods consist essentially of introducing a pulse of a metal-containing precursor into a reactor having at least one substrate disposed therein, the reactor being at a temperature that is lower than a decomposition temperature of the metal-containing precursor, saturating a surface of the at least one substrate with at least part of the metal-containing precursor, forming a metal layer on the at least one substrate by increasing the temperature of the reactor to a temperature that is higher than the decomposition temperature of the metal-containing precursor during the purge cycle, and repeating these steps until a metal film having the desired thickness is obtained.

Each of the disclosed methods may include one or more of the following aspects:
repeating the method steps;
the concentration of the metal in the metal layer ranging from approximately 70 atomic % to approximately 100 atomic %, preferably approximately 90 atomic % to approximately 100 atomic %;
the lower temperature ranging between about 20° C. and about 400° C., preferably between about 50° C. and about 300° C.;
the higher temperature ranging between about 100° C. to and about 600° C.;
decreasing the temperature from the higher temperature to the lower temperature by backside gas cooling or by high flow gas cooling;
the metal-containing precursor being selected from the group consisting of AlH₃.tertiary amine, AlH₃.cyclic amine, AlH₂(BH₄), and AlH₂(BH4):tertiary amine;
the metal-containing precursor being selected from the group consisting of AlH₃.NMe₂Et, AlH₃.methylpyrrolidine, and AlH₂(BH₄):NMe₃;
a metal of the metal-containing precursor having an oxidation state of 0;
the metal-containing precursor being selected from the group consisting of tungsten(tricarbonyl)(benzene) [W(Bz)(CO)₃], molybdenum(tricarbonyl)(benzene) [Mo(Bz)(CO)₃], ruthenium(toluene)(cyclohexadiene), ruthenium(cyclohexadiene)(tricarbonyl) [Ru(Chd)(CO)₃], Ru₃(CO)₁₂, ruthenium(methyl-cyclohexadiene)(tricarbonyl) [Ru(Me-CHD)(CO)₃], and tantalum bis(mesitylene), and niobium bis(mesitylene);
the metal being a noble metal; and
the metal-containing precursor being selected from the group consisting of ruthenium(toluene)(cyclohexadiene), ruthenium(cyclohexadiene)(tricarbonyl) [Ru(Chd)(CO)₃], ruthenium(methyl-cyclohexadiene)(tricarbonyl) [Ru(Me-CHD)(CO)₃], and Ru₃(CO)₁₂.

### Notation and Nomenclature

Certain terms are used throughout the following description and claim to refer to particular system components.

The standard abbreviations of the elements from the periodic table of elements are used herein. It should be understood that elements may be referred to by these abbreviations (e.g., Ru refers to ruthenium, Ta refers to tantalum, Nb refers to niobium, etc).

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation, “Me,” refers to a methyl group; the abbreviation, “Et,” refers to an ethyl group; the abbreviation, “Pr,” refers to a propyl group; the abbreviation, “iPr,” refers to an isopropyl group; the abbreviation “Bu” refers to butyl (n-butyl); the abbreviation “tBu” refers to tert-butyl; the abbreviation “sBu” refers to sec-butyl; the abbreviation “Cp” refers to cyclopentadienyl; the abbreviation “chd” refers to cyclohexadienyl; the abbreviation “Bz” refers to benzene; the abbreviation “cod” refers to cyclooctadienyl; the abbreviation “acac” refers to acetylacetonate; the abbreviation “R-NacNac” refers to N-alkyl diketiminate; the abbreviation “R-acNac” refers to N-alkyl ketomininate, also known as enaminoketonate; the abbreviation “hfac” refers to hexafluoroacetylacetonato; the abbreviation “tmhd” refers to 2,2,6,6-tetramethyl-3,5-heptadionato; the abbreviation “od” refers to 2,4-octadionato; the abbreviation “dmamp” refers to 1-dimethylamino-2-methyl-2-propanolate; the abbreviation “DIBM” refers to 2,6-dimethyl-3,5-heptanedionato; and the abbreviation “MABO” refers to 1-dimethylamino-2-methyl-2butoxy.

### BRIEF DESCRIPTION OF THE DRAWINGS

For a further understanding of the nature and objects of the present invention, reference should be made to the following detailed description, taken in conjunction with the accompanying drawings, wherein:

FIG. 1 is a graph illustrating ruthenium film thickness versus cycle on a TaN substrate; and

FIG. 2 is a graph illustrating ruthenium film thickness versus cycle on a ruthenium substrate.

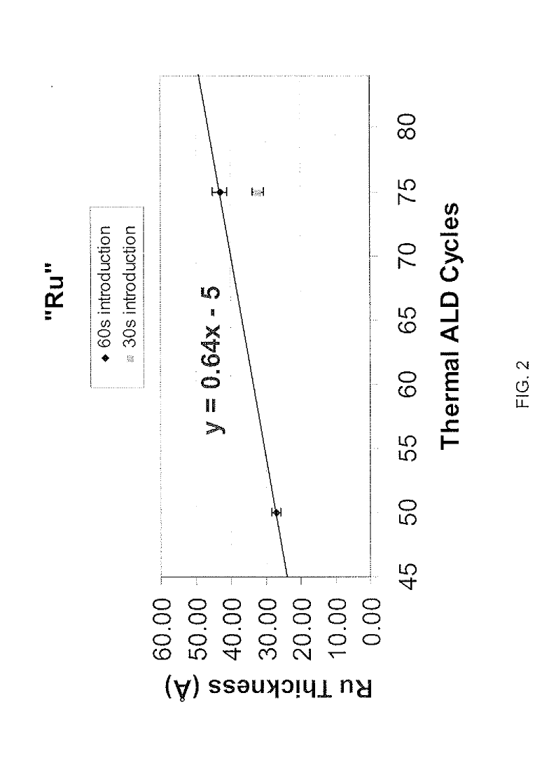

### DETAILED DESCRIPTION OF PREFERRED EMBODIMENTS

Disclosed are modified Atomic Layer Deposition (ALD) processes used to deposit metal films on a substrate. The disclosed methods may be useful in the manufacture of semiconductor, photovoltaic, LCD-TFT, or flat panel type devices. Also disclosed is a modified ALD reactor suitable to practice the disclosed methods.

The disclosed methods include setting a temperature in a reactor containing at least one substrate, introducing a pulse of a metal-containing precursor into the reactor, saturating a surface of the at least one substrate with at least part of the metal-containing precursor, and removing a portion of the at least part of the metal-containing precursor to form a metal layer exclusively by increasing the temperature of the reactor to a temperature that is higher than a decomposition temperature of the metal-containing precursor. The concentration of the metal in the resulting metal layer ranges from approximately 70 atomic % to approximately 100 atomic %, preferably approximately 90 atomic % to approximately 100 atomic %.

Alternatively, the disclosed methods include introducing a pulse of a metal-containing precursor into a reactor having at least one substrate disposed therein, the reactor being at a temperature that is lower than a decomposition temperature of the metal-containing precursor, saturating a surface of the at least one substrate with at least part of the metal-containing precursor, and forming a metal layer on the at least one substrate exclusively by increasing the temperature of the reactor to a temperature that is higher than the decomposition temperature of the metal-containing precursor.

The term “exclusively” means that no other step is used to perform the recited step. In other words, only the temperature is increased in order to remove a portion of the at least part of the metal-containing precursor or only the temperature is increased to form a metal layer. The use of a reactant is not required in the recited steps.

In another alternative, the disclosed methods consist essentially of setting a temperature in a reactor containing at least one substrate, introducing a pulse of a metal-containing precursor into the reactor, saturating a surface of the at least one substrate with at least part of the metal-containing precursor, removing a portion of the at least part of the metal-containing precursor to form a metal layer by increasing the temperature of the reactor to a temperature that is higher than a decomposition temperature of the metal-containing precursor during the purge cycle, and repeating these steps until a metal film having the desired thickness is obtained.

In another alternative, the disclosed methods consist essentially of introducing a pulse of a metal-containing precursor into a reactor having at least one substrate disposed therein, the reactor being at a temperature that is lower than a decomposition temperature of the metal-containing precursor, saturating a surface of the at least one substrate with at least part of the metal-containing precursor, forming a metal layer on the at least one substrate by increasing the temperature of the reactor to a temperature that is higher than the decomposition temperature of the metal-containing precursor during the purge cycle, and repeating these steps until a metal film having the desired thickness is obtained.

The phrase “consists essentially of” limits the disclosed methods to the specified steps plus any steps that do not materially affect the basic and novel characteristics of the disclosed methods. More particularly, in one alternative, Applicants intend for the claimed method to produce a metal film without the use of a reactant. However, if additional processing occurs, such as the addition of another metal to the metal film to produce a bimetal film, a reactant may be used if needed to deposit the additional metal. In a second alternative, the scope of the method is limited to producing the metal film, without the addition of another metal.

Suitable metal-containing precursor include any organometallic precursor containing a metal selected from Column 3 through Column 12 of the Periodic Table, Al, Ga, In, TI, Ge, Sn, Pb, Sb, and Bi. Preferably, the metal-containing precursor contains a noble metal (i.e., Ru, Rh, Pd, Ag, Re, Os, Ir, Pt, Au, and Hg).

In one alternative, the metal of the metal-containing precursor has an oxidation state of 0. The ligands are more easily removed from a compound with a metal having an oxidation state of 0 than from a metal having a higher oxidation state because both the metal and the ligands dissociate as neutral species. Applicants believe that dissociation of compounds having a metal with an oxidation state of 0 does not require the use of a reactant, such as H₂, but only heat. Applicants believe that some compounds with metals having a higher oxidation state may require the use of a reducing agent in order to form the metal film. However, depending upon the metal and the ligands, the disclosed methods may be suitable for use with some metals that have an oxidation state higher than 0. Exemplary metal-containing precursors in which the metal has an oxidation state of 0 include but are not limited to ruthenium(toluene)(cyclohexadiene), Ru₃(CO)₁₂, ruthenium (cyclohexadiene)(tricarbonyl), tungsten(tricarbonyl)(benzene) [W(Bz)(CO)₃], molybdenum(tricarbonyl)(benzene) [Mo(Bz)(CO)₃], niobium bis(mesitylene), and tantalum bis(mesitylene). The cyclohexadiene group of the Ru compounds may be independently substituted by one or multiple C₁ to C₆ alkyl groups, e.g., Ru(Me-cyclohexadiene)(CO)₃. These exemplary metal-containing precursors are commercially available.

The metal-containing precursor should have a suitable decomposition temperature for use in the disclosed methods. One of ordinary skill in the art will recognize that molecular decomposition does not occur at one specific temperature, but instead occurs over a range of temperatures. The claimed decomposition temperature is the maximum temperature allowing self-saturated surface saturation. Exemplary metal-containing precursors suitable for use in the disclosed methods along with their decomposition temperature are provided in Table 1 below:

| | Decomposition | |
|---|---|---|
| Precursor | Temperature | |
| Al | | |
| AlH₃•tertiary amine | ~120° | C. |
| AlH₃•cyclic amine | ~120° | C. |
| AlH₂(BH₄)and AlH₂(BH₄):tertiary amine | ~120° | C. |
| TriMethyl Aluminum | >350° | C. |
| AlH₃•methylpyrrolidine | ~130° | C. |
| alanes: R₃N:AlH₃, wherein R is alkyl | ~120° | C. |
| NMe₃:AlH₃ (TMAA) | ~120° | C. |
| Me₂EtN:AlH₃ (DMEAA) | ~120° | C. |
| AlH₂(BH₄)ₓN(CH₃)₃ (TMAAB) | ~120° | C. |
| Nb | | |
| NbCl₅ | 320° | C. |
| niobium bis(mesitylene) | 200° | C. |
| Zn | | |
| DiEthyl Zinc | ~300° | C. or more |
| Co | | |
| Co(CO)₂Cp | <200° | C. |
| dicobalt hexacarbonyl t-butylacetylene | <200° | C. |
| (Co-CCTBA) | | |
| Ir | | |
| Ir(acac)₃ | ~400° | C. |
| Ni | | |
| Ni(Et-NacNac)₂ | <~300° | C. |
| Ni(RCp)-pyrrolcarbodiminates, R = alkyl | <~300° | C. |
| Mn | | |
| Mn(RCp), R = alkyl | >200° | C. |
| Ru | | |
| bis(2,6,6-trimethyl- | <350° | C. |
| cyclohexadienyl)ruthenium | | |
| RuO₄ | <150° | C. |
| Ru(Me-chd)(CO)₃ | ~225-250° | C. |
| Ru(Chd)(CO)₃ | ~225-250° | C. |
| Ru(EtCp)₂ | ~400° | C. |
| Pt | | |
| Pt(Me)₃(MeCp) | ~300° | C. |
| Pt(Me)₃(RCp) | >200° | C. |
| Cu | | |
| Cu(R-NacNac)₂, R = alkyl | <200° | C. |
| Cu(R-acNac)₂, R = alkyl | <200° | C. |
| Cu(acac)(PR₃)ₓ, x = 1-4, R = alkyl | <250° | C. |
| Ti | | |
| Tetrakis(dimethylamino)titanium | <275° | C. |
| (TDMAT) | | |
| Tetrakis(ethylmethylamino)titanium | <275° | C. |
| (TEMATi) | | |
| Ti(NMe₂)(RCp), R = 1 or multiple alkyl | <325° | C. |
| Ti(OMe)₃(RCp), R = 1 or multiple alkyl | <400° | C. |

Specific exemplary metal-containing precursors that are included in the structures listed in Table 1 include AlH₃.NMe₂Et, AlH₃.methylpyrrolidine, AlH₂(BH₄), AlH₂(BH₄):NMe₃, and Cu(acac)[P(CH₃CH₂CH₂CH₂)₃]₂. The amine groups of these compounds may be independently substituted by one or multiple C₁ to C₆ alkyl groups. These exemplary metal-containing precursors are commercially available.

Applicants believe that the metal-containing precursors in Table 2 have decomposition temperatures below 500° C., and potentially below 400° C. As a result, the metal-containing precursors in Table 2 may also be used in the disclosed methods. These metal-containing precursors are either commercially available or may be synthesized by methods known in the literature.

| Precursor | Precursor |
|---|---|
| Mn(RCp)(CO)₃, R = alkyl | Ir(EtCp)cod |
| Ru(dimethylpentadienyl)₂ | Ir(tmhd)₃ |
| Ru₃(CO)₁₂ | IrF₆ |
| ruthenium(toluene)(R- | Bis(1-dimethylamino-2-methyl-2- |
| cyclohexadiene), R = alkyl | butoxy)nickel (MABO-Ni) |
| Ru(arene)(diene) | Ni(CO)₄ |
| Ru(arene)(norbornadiene) | Bis(1-dimethylamino-2-methyl-2- |
| | propanolate)nickel [Ni(dmamp)₂] |
| Ru(arene)(cyclooctadiene) | NiCp₂ |
| Ru(arene)(butadiene) | Ni(EtCp)₂ |
| Ru(CO)₂-allyl | Ni(MeCp)₂ |
| Ru(EtCp)(Me₂Op) | Ni(PF₃)₄ |
| Ru(Me₂Cp)₂ | NiCp(allyl) |
| Ru(Me₂Op)₂ | Ni(allyl)(R-NacNac), R = Alkyl |
| Ru(MeCp)₂ | Ni(allyl)-R-pyrrolcarbodiminates, |
| | R = alkyl |
| Ru(od)₃ | Pd(Cp)COD |
| Ru(tmhd)₂(cod) | Pd-allyl |
| Ru(Cp)₂ | Pd(Me-allyl)₂ |
| Diborane | Pd(Cp)allyl |
| Silane | Pd(acac)₂ |
| Disilane | Pd(R-acNac)₂, R = alkyl |
| Dimethyltellurium | Pd(R-NacNac)₂, R = alkyl |
| Di-tert-butyl telluride (DtBuTe) | Pd(allyl)(R-NacNac), R = alkyl |
| Sb(R₃), R = Me and/or Et and/or iPr | Au(R₃P)Cl, R = alkyl |
| Te(R₃), R = Me and/or Et and/or iPr | Au(CO)Cl |
| and/or tBu | |
| [TeMe]₂ | pentakis dimethylamino |
| | tantalum [PDMAT or (Me₂N)₅Ta] |
| GeHₓR_{y}, x, y >= 0, R = alkyl | TiCl₄ |
| GeCl₂:adducts (ex:dioxane) | tetrakis dimethylamino |
| | vanadium [TDMAV or (Me₂N)₄V] |
| MoCl₅ | TaCl₅ |
| Mo(CO)₆ | TaCl₅:SEt₂ |
| MoF₆ | Tertiary amylimido- |
| | tris(dimethylamido)tantalum |
| | (TAIMATA) |
| Mo(Bz)(CO)₃ | Tantalum ethoxide (TAETO) |
| Nb | Ta(NtBu)(Me₂)Cp |
| NbCl₅ | TaF₅ |
| niobium bis(mesitylene) | Tert-butylimido tris-diethylamido |
| | tantalum (TBTDET) |
| Dimethyl Zinc | tantalum bis(mesitylene) |
| W(Bz)(CO)₃ | PtCp(allyl) |
| WF₆ | Pt(PF₃)₄ |
| WH₂(RCp)₂, R = alkyl | Pt(acac)₂ |
| Co(EtCp)₂ | Pt(CO₂)Cl₂ |
| CoCp₂ | Pt(Me)₃Cp |
| Co(R-NacNac)₂, R = alkyl | Pt(allyl)₂ |
| Co(RCp)(amidinate), R = alkyl | Pt(Me)₂COD |
| Co(R-acNac)₂, R = alkyl | Cu(hfac)(PMe₃) |
| Co(acac)₂ | Cu amino-alkoxide |
| Co(MeCp)₂ | Cu(hfac)₂ |
| | Bis(2,6-dimethyl-3,5- |
| | heptanedionato)copper |
| | (Cu(DIBM)₂) |
| | Bis(1-dimethylamino-2methyl-2- |
| | butoxy)copper (MABO-Cu) |

The metal-containing precursors may be supplied either in neat form or in a blend with a suitable solvent, such as ethyl benzene, xylene, mesitylene, decane, dodecane. The metal-containing precursors may be present in varying concentrations in the solvent.

The neat or blended precursor is introduced into a reactor in vapor form by conventional means, such as tubing and/or flow meters. The precursor in vapor form may be produced by vaporizing the neat or blended precursor solution through a conventional vaporization step such as direct vaporization, distillation, or by bubbling. The neat or blended precursor may be fed in liquid state to a vaporizer where it is vaporized before it is introduced into the reactor. Alternatively, the neat or blended precursor may be vaporized by passing a carrier gas into a container containing the precursor or by bubbling the carrier gas into the precursor. The carrier gas may include, but is not limited to, Ar, He, N₂, and mixtures thereof. Bubbling with a carrier gas may also remove any dissolved oxygen present in the neat or blended precursor solution. The carrier gas and precursor are then introduced into the reactor as a vapor.

If necessary, the container of metal-containing precursor may be heated to a temperature that permits the precursor to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of precursor vaporized.

The reactor may be any enclosure or chamber within a device in which deposition methods take place such as without limitation, a parallel-plate type reactor, a cold-wall type reactor, a hot-wall type reactor, a single-wafer reactor, a multi-wafer reactor, or other types of deposition systems.

Generally, the reactor contains one or more substrates onto which the thin films will be deposited. The substrates are generally located on a susceptor or support pedestal inside the reactor. The substrate may alternatively be located on a wall of the reactor, for example, in a column reactor. The susceptor, support pedestal, or wall may include heating and/or cooling means. Suitable heating means include lamp heaters, lasers, inductive heaters, mechanical heaters (hot plate, hot chuck), infrared heaters, furnace, incandescent heaters, flash annealers, spike annealers, or any combination thereof. The heating means may be near or in contact with the susceptor, support pedestal, or wall. Suitable cooling means include backside gas cooling or high flow gas cooling. Backside gas cooling supplies a cold gas, such as liquid nitrogen, He, etc., to the backside of the substrate or susceptor or between the susceptor and the wafer. High flow gas cooling injects a cold inert gas, such as He, Ar, N2, etc., into the chamber to cool the substrate and possibly the chamber.

Exemplary reactors suitable for use with the disclosed methods include the low profile, compact atomic layer deposition reactor disclosed in U.S. Pat. No. 5,879,459, the contents of which are incorporated herein by reference. The apparatus has a substrate processing region adapted to enclose the substrate during processing and a retractable support pedestal extendable into the substrate processing region (claim 1). The apparatus further comprises a heater adapted for heating the substrate supported on the support pedestal and cooling lines for passing coolant through a portion of the reactor (claim 3).

Another exemplary reactor that may be modified for use with the disclosed methods includes the rapid thermal process reactor disclosed in U.S. Pat. No. 6,310,327, the contents of which are incorporated herein by reference. The apparatus has a rapid thermal process reaction chamber, a rotatable rapid thermal process susceptor mounted within the rapid thermal is process reaction chamber, and a rapid thermal process radiant heat source mounted outside the rapid thermal process reaction chamber (claim 1). The reaction chamber would need to be modified to include a precursor inlet. The rapid thermal process radiant heat source may be a plurality of lamp banks, with each lamp bank having a quartz-halogen lamp (claims 25 and 26). The apparatus may further comprise a heater, such as a resistance heater, mounted in the rapid thermal process reaction chamber beneath the rotatable rapid thermal process susceptor (claims 2 and 3). The rapid thermal process reaction chamber may be bound by a vessel having a water-cooled side wall, a water-cooled bottom wall, and a forced-air-cooled top wall (claim 23).

Rather than mounting the radiant heat source outside of the reactor, a laser or lamp array may be located inside the reactor above the susceptor. A recirculating chiller and temperature sensors may be located within the susceptor. Such an exemplary reactor is disclosed in FIGS. 3 and 4 of U.S. Pat. No. 7,601,393.

The reactor may be a bell jar furnace having a vertical temperature gradient, with the top of the bell jar furnace being warmer than the bottom of the bell jar furnace. One or more wafers may be located on a susceptor that may be moved from the warm section to the cool section of the bell jar furnace depending upon the process step.

Alternatively, the reactor may include two separate chambers, with the metal-containing precursor being introduced into the first chamber at a temperature below the decomposition temperature of the precursor and saturating the surface of the substrate and then the saturated substrate being moved to the second chamber at a temperature that is higher than the decomposition temperature of the precursor. In this alternative, cooling means are not required because both chambers may be maintained at the desired temperatures.

The substrates located within the reactor may be any suitable substrate used in semiconductor, photovoltaic, flat panel, or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium, or gold) may be used. The substrate may also have one or more layers of differing materials already deposited upon it from a previous manufacturing step.

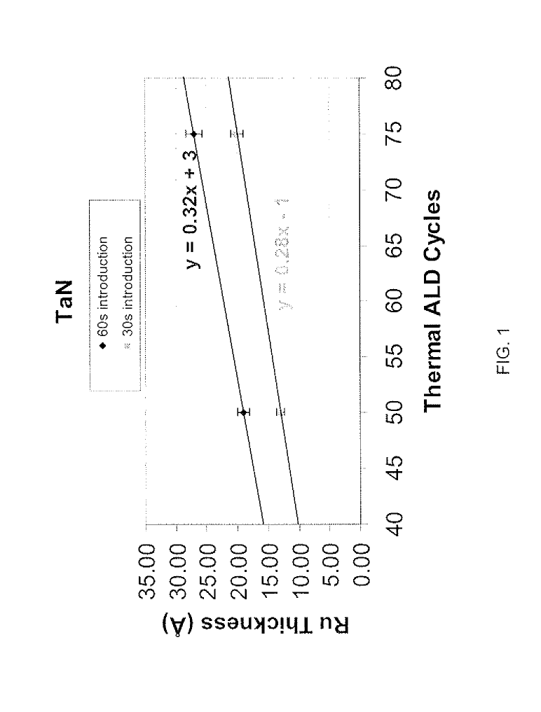

In the disclosed method, the temperature and the pressure within the reactor are adjusted depending upon the cycle in the ALD process. The temperature of the reactor may be controlled by either controlling the temperature of the susceptor or, as depicted in FIG. 1, controlling the temperature of the reactor wall, which may or may not also function as the substrate holder. During introduction of the disclosed precursor, the pressure in the reactor may be held between about 0.0001 torr (0.013 Pa) and about 1000 torr (133,322 Pa), preferably between about 0.1 torr (13 Pa) and 10 torr (1,333 Pa). Likewise, the temperature in the reactor may be held between about 20° C. and about 400° C., preferably between about 50° C. and about 300° C. As discussed previously, the temperature should be below the decomposition temperature of the metal-containing molecule. For example, for AlH₃.tertiary amine having a decomposition temperature of approximately 120° C., the temperature may be 100° C. In another example, for diethyl zinc having a decomposition temperature of approximately 300° C., the temperature may be 275° C.

The conditions within the chamber allow at least part of the metal-containing precursor to deposit onto or saturate the substrate. Applicants believe that during deposition, at least one of the ligands attached to the metal may detach, freeing the metal to bond with the substrate surface in a process known as adsorption/chemisorption.

The temperature and optionally the pressure within the reactor may then be adjusted so that any remaining ligands in the metal-containing precursor are broken, leaving only the metal bonded to the substrate in a process known as decomposition. Applicants believe that increasing the temperature within the reactor to above the decomposition temperature of the metal-containing precursor provides sufficient conditions for this decomposition step. Depending upon the heating means and the thermal conductive qualities of the reactor, the temperature may be increased very quickly, perhaps in as little as a few milliseconds. Alternatively, the temperature and pressure may be adjusted by transferring the saturated substrate from one chamber to another chamber of the reactor.

Care must be taken to avoid heating the reactor to a temperature that may initiate reaction among the remaining parts of the metal-containing precursor. Such conditions may result in contamination of the resulting film with undesirable impurities, such as C, N or O. Temperature may range between about 100° C. to about 1050° C., preferably between about 100° C. to and about 600° C. As discussed previously, the temperature should be above the decomposition temperature of the metal-containing molecule. For example, for AlH₃.tertiary amine having a decomposition temperature of approximately 120° C., the temperature may be 150° C. In another example, for diethyl zinc having a decomposition temperature of approximately 300° C., the temperature may be 400° C.

The pressure within the reactor may also optionally be adjusted to further facilitate decomposition. Exemplary pressures range between about 0.01 torr (1.3 Pa) to about 200 torr (26,664 Pa), preferably between about 0.01 torr (1.3 Pa) to about 10 torr (1,333 Pa).

The decomposition step, i.e. at least raising the temperature of the chamber, may be performed simultaneously with purging any excess metal-containing precursor from the chamber. In the purging step, any excess metal-containing precursor is removed from the reactor by purging with N₂, H₂, Ar, He, or mixtures thereof. Alternatively, the decomposition step may occur after purging. In the disclosed methods, the use of a reactant to form the metal film on the substrate is not required.

If a metal film having the desired thickness has been obtained, the process is complete. If not, the process may be repeated until a film having the desired thickness is obtained. When the process is repeated, care must be taken in exposing the wafer to the temperature change from above its decomposition temperature to below its decomposition temperature (i.e., the cooling step). The cooling rate must be limited so that wafer and films on it are not negatively affected by thermal stresses. The cooling rate will be determined on case by case basis, dependant at least upon the composition of the substrate, the number of layers on the substrate, and the metal film being deposited.

Upon obtaining a desired film thickness, the film may be subject to further processing, such as furnace-annealing, rapid thermal annealing, UV or e-beam curing, and/or plasma gas exposure. Those skilled in the art recognize the systems and methods utilized to perform these additional processing steps.

Depending on what type of film is desired to be deposited, a second precursor may be introduced into the reactor. The second precursor comprises another metal source, such as Ti, Ta, Bi, Hf, Zr, Pb, Nb, Mg, Al, Ni, Cu, Co, Fe, Mn, Ln, or combinations thereof. The use of a reactant, such as H₂, NH₃, O₃, O₂, etc., may be required to deposit the metal of the second metal-containing on the substrate. When a second metal-containing precursor is utilized, the resultant film deposited on the substrate may contain at least two different metal types.

The metal-containing precursor and any optional second metal-containing precursors and/or reactants are introduced sequentially into the reaction chamber. The reaction chamber may be purged with an inert gas such as N₂, H₂, Ar, He, or combinations thereof between the introduction of the precursors and the optional reactants.

The vaporized precursor and any optional second metal-containing precursors and optional reactants may be pulsed sequentially. Each pulse of precursor may last for a time period ranging from about 0.01 seconds to about 10 seconds, alternatively from about 0.3 seconds to about 3 seconds, alternatively from about 0.5 seconds to about 2 seconds. The optional reactant may also be pulsed into the reactor. The pulse of each gas may last for a time period ranging from about 0.01 seconds to about 10 seconds, alternatively from about 0.3 seconds to about 3 seconds, alternatively from about 0.5 seconds to about 2 seconds.

Depending on the particular process parameters, deposition may take place for a varying length of time. Generally, deposition may be allowed to continue as long as desired or necessary to produce a film with the necessary properties. The deposition process may also be performed as many times as necessary to obtain the desired film.

In one non-limiting exemplary ALD type process, the vapor phase of the metal-containing precursor is introduced into the reactor at a temperature of 200° C. and a pressure of 2 Torr (267 Pa), where it is contacted with a suitable substrate. Excess precursor may then be removed from the reactor by purging with N₂, Ar, He, or mixtures thereof and/or evacuating the reactor at a pressure of 0.5 Torr (67 Pa). The temperature of the reactor may be increased to 500° C. and the pressure to 3 Torr (400 Pa) during or after the purge step. If the desired film is a metal film, this two-step process may provide the desired film thickness or may be repeated until a film having the necessary thickness has been obtained.

Alternatively, if the desired film is a bimetal film, the two-step process above may be followed by introduction of the vapor of a second metal-containing precursor into the reactor at a temperature ranging from about 50° C. and about 400° C., preferably between about 100° C. and about 350° C. and a pressure that may range between about 0.01 torr (1.3 Pa) to about 200 torr (26,664 Pa), preferably between about 0.01 torr (1.3 Pa) to about 10 torr (1,333 Pa). The second metal-containing precursor will be selected based on the nature of the bimetal film being deposited. After introduction into the reactor, the second metal-containing precursor is contacted with the substrate. Any excess second metal-containing precursor is removed from the reactor by purging and/or evacuating the reactor. A reactant may be introduced into the reactor at a temperature ranging from about 300° C. and about 600° C., and a pressure that may range between about 0.01 torr to about 200 torr, preferably between about 0.01 torr to about 10 torr to react with the second metal-containing precursor. Excess reactant is removed from the reactor by purging and/or evacuating the reactor.

If a desired film thickness has been achieved, the process may be terminated. However, if a thicker film is desired, the entire process may be repeated. By alternating the provision of the metal-containing precursor, the optional second metal-containing precursor, and the optional reactant, a film of desired composition and thickness can be deposited.

When the optional reactant in this exemplary ALD process is treated with a plasma, the exemplary ALD process becomes an exemplary PEALD process. The optional reactant may be treated with plasma prior or subsequent to introduction into the chamber.

The metal films or bimetal-containing layers resulting from the processes discussed above may include the pure metal (M) or bimetal (M₁M₂) films, such as a metal silicate (MeₖSiₗ), wherein k and l are integers which inclusively range from 1 to 10. One of ordinary skill in the art will recognize that by judicial selection of the appropriate disclosed precursor, optional second metal-containing precursors, and reactant species, the desired film composition may be obtained.

### EXAMPLES

The following non-limiting examples are provided to further illustrate embodiments of the invention. However, the examples are not intended to be all inclusive and are not intended to limit the scope of the inventions described herein.

### Prophetic Example 1

ALD deposition of molecules having the formula Ru(chd)(bz) require reaction with O₂ to produce a film. However, O₂ is not desired for Back End Of the Line (BEOL) applications.

Applicants believe that using molecules having the formula Ru(chd)(bz) in the disclosed method will produce a film without the use of O₂.

### Prophetic Example 2

ALD deposition of molecules having the formula Ru(chd)(CO)₃ require reaction with O₂ to produce a film. However, O₂ is not desired for Back End Of the Line (BEOL) applications.

Applicants believe that using molecules having the formula Ru(chd)(CO)₃ in the disclosed method will produce a film without the use of O₂.

### Prophetic Example 3

CVD deposition of Al molecules is well known. Deposition of an Al-film using Al-containing compounds such as AlH₃.NMe₂Et, AlH₃.methylpyrrolidine, and AlH₂(BH₄):NMe₃ may occur without the use of a reactant using the disclosed method. More particularly, the Al-containing precursor may be introduced into the reactor at a temperature of approximately 50° C. Excess precursor may be removed from the reactor by purging with N₂. The temperature of the reactor may then be raised to 150° C. Applicants believe that this process will produce an Al film on the substrate.

### Example 4

Ru(Me-chd)(CO)₃ was placed in a bubbler. The precursor delivery was ensured with a N₂ carrier flow of 50 sccm maintaining the bubbler pressure at 50 torr (6,666 Pa) and room temperature. The reactor, a 60 cm long hot wall chamber, was maintained at a constant pressure ˜0.7 Torr (93 Pa) and had a constant N₂ flow to help maintain a stable pressure, enhance gas flow and purging. The schematic of the reactor used for the deposition is depicted in FIG. 1. TaN and Ru substrates were disposed in the chamber/furnace.

During Ru(Me-chd)(CO)₃ introduction, the reactor temperature was fixed at 200° C. After introducing Ru(Me-chd)(CO)₃ during a time long enough to ensure surface saturation (up to one minute of precursor introduction was used) the chamber was purge with a N₂ flow.

During the purge time, the reactor temperature was raised up to 500° C. After one minute at 500° C., the reactor temperature was decreased down to 200° C.

The cycle was repeated to grow a film of a determined thickness.

The same experiment varying the introduction time of Ru(me-chd)(CO)₃ was performed on various substrates (TaN and Ru). The number of cycles was also varied. The film thickness was measured by ellipsometry.

A growth rate as high as ˜0.3 A/cycle was achieved on TaN with 60s precursor introduction. ˜0.6 A/cycle was achieved on Ru. A slightly lower growth rate is seen with only 30 s of precursor introduction indicating a non-complete surface saturation. It is to be understood that the introduction time can be lowered by increasing the precursor flow and enhancing the reactor design to achieve faster surface saturation.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

1. A method for depositing a metal layer onto one or more substrates, comprising the steps of:
(a) introducing a pulse of a metal-containing precursor into a reactor having at least one substrate disposed therein, the reactor being at a temperature that is lower than a decomposition temperature of the metal-containing precursor;
(b) saturating a surface of the at least one substrate with at least part of the metal-containing precursor; and
(c) forming a metal layer on the at least one substrate exclusively by increasing the temperature of the reactor to a temperature that is higher than the decomposition temperature of the metal-containing precursor.

2. The method of claim 1, wherein a metal of the metal-containing precursor having an oxidation state of 0.

3. The method of claim 1, wherein the metal-containing precursor is selected from the group consisting of tungsten(tricarbonyl)(benzene) [W(Bz)(CO)₃], molybdenum(tricarbonyl)(benzene) [Mo(Bz)(CO)₃], ruthenium(toluene)(cyclohexadiene), ruthenium(cyclohexadiene)(tricarbonyl) [Ru(Chd)(CO)₃], Ru₃(CO)₁₂, ruthenium(methyl-cyclohexadiene)(tricarbonyl) [Ru(Me-CHD)(CO)₃], and tantalum bis(mesitylene), and niobium bis(mesitylene).

4. The method of claim 1, further comprising repeating steps (a) through (c).

5. The method of claim 1, further comprising (d) decreasing the temperature of the reactor to the temperature that is lower than the decomposition temperature of the metal-containing precursor.

6. The method of claim 5, wherein the temperature is decreased by backside gas cooling or by high flow gas cooling.

7. A metal layer ALD method, the method comprising:
(a) setting a temperature of a reactor, the reactor containing at least one substrate;
(b) introducing a pulse of a metal-containing precursor into the reactor;
(c) saturating a surface of the at least one substrate with at least part of the metal-containing precursor; and
(d) removing a portion of the at least part of the metal-containing precursor to form a metal layer on the substrate exclusively by increasing the temperature of the reactor to a temperature that is higher than a decomposition temperature of the metal-containing precursor, wherein a concentration of a metal in the metal layer is greater than approximately 70 atomic % preferably greater than 90 atomic %.

8. The method of claim 7, wherein a metal of the metal-containing precursor having an oxidation state of 0.

9. The method of claim 7, wherein the metal-containing precursor is selected from the group consisting of tungsten(tricarbonyl)(benzene) [W(Bz)(CO)₃], molybdenum(tricarbonyl)(benzene) [Mo(Bz)(CO)₃], ruthenium(toluene)(cyclohexadiene), ruthenium(cyclohexadiene)(tricarbonyl) [Ru(Chd)(CO)₃], Ru₃(CO)₁₂, ruthenium(methyl-cyclohexadiene)(tricarbonyl) [Ru(Me-CHD)(CO)₃], and tantalum bis(mesitylene), and niobium bis(mesitylene).

10. The method of claim 7, further comprising repeating steps (a) through (d).

11. The method of claim 11, wherein the temperature is decreased from step (d) to step (a) by backside gas cooling or by high flow gas cooling
